(19) United States
(12) Patent Application Publication
(10) Pub. No.: US 2020/0227676 A1
(43) Pub. Date: Jul. 16, 2020

(54) ORGANIC LIGHT-EMITTING DIODE DISPLAY DEVICE

(71) Applicant: WUHAN CHINA OPTOELECTRONICS TECHNOLOGY CO., LTD., Wuhan (CN)

(72) Inventor: Yuejun TANG, Wuhan (CN)

(21) Appl. No.: 16/348,153

(22) PCT Filed: Feb. 1, 2019
(86) PCT No.: PCT/CN2019/074322

§ 371 Date: May 8, 2019

(30) Foreign Application Priority Data
Nov. 30, 2018 (CN) 201811456788.1

(51) Int. Cl. H01L 51/52

(52) U.S. Cl. CPC H01L 51/5253; H01L 2251/5338; H01L 51/5246; H01L 51/5203

(57) ABSTRACT

An organic light-emitting diode (OLED) display device is provided. The OLED display device includes a substrate, a light-emitting layer, and a packaging layer. A signal trace and a bonding terminal are disposed on an external surface of the packaging layer, so that the OLED display device has an adequate surface space to reduce attenuation, delay, and nonuniformity. Therefore, a narrow frame of the display device can be advantageously achieved.

### BACKGROUND OF INVENTION

### Field of Invention

The present invention relates to a technical field of semiconductor display, and more particularly, to an organic light-emitting diode display device.

### Description of Prior Art

Organic light-emitting diode (OLED) display devices have advantages of being thin, being light, wide viewing angles, active illumination, continuously adjustable colors, low cost, fast response times, low energy consumption, wide operating temperature ranges, simple manufacturing processes, high luminous efficiency, and flexible display. The OLED display devices have become a very important display technology field of flat panel displays.

The OLED display devices are different from liquid crystal display (LCD) devices. The OLED display devices have a self-luminescence property and do not use separate light sources, so they can be thinner and lighter than display devices with the separate light sources. Therefore, the OLED display devices can be relatively flexible and foldable.

However, as for large-sized OLED display devices, display signals are transmitted from a bonding terminal to each part of the display devices, and the display quality is degraded because the large-sized OLED display devices have attenuation, delay, and non-uniformity of transmission of the signals.

### SUMMARY OF INVENTION

In one embodiment, an organic light-emitting diode (OLED) display device is provided, and a signal trace and a bonding terminal are disposed on an external surface of a packaging layer, so that the OLED display device has an adequate surface space to dispose a low resistance trace. Meanwhile, a bending extension region is disposed on at least one side of the substrate, and display signals can be transmitted nearby so as to reduce attenuation, delay, and nonuniformity. Therefore, the narrow frame of the display device can be advantageously achieved.

In order to solve above mentioned problems, an OLED display device is provided by one embodiment of the present invention. The OLED display includes a substrate having at least one connection end, a light-emitting layer formed on the substrate, and a packaging layer covering the light-emitting layer. The packaging layer has at least one connection end formed thereon, and the at least one connection end of the packaging layer is disposed corresponding to the at least one connection end of the substrate, and a signal trace and a bonding terminal are disposed on a surface of the packaging layer, a bending extension region is disposed on at least one side of the substrate, the bending extension region is bent to a surface of the packaging layer to electrically connect the at least one connection end of the substrate to the at least one connection end of the packaging layer, and the at least one connection end of the substrate and the at least one connection end of the packaging layer are connected to the bonding terminal through the signal trace to transmit a display signal. An actual width of the bending extension region is greater than a default width of the bending extension region, and the at least one connection end of the packaging layer is disposed at a position of the surface of the packaging layer for which a projection of the display region to the packaging layer is located. The bonding terminal is disposed at an intermediate position of an outside the packaging layer.

In one embodiment, the packaging layer is a packaging cover plate.

In one embodiment, the packaging cover plate and the substrate seal the light-emitting layer by an encapsulant.

In one embodiment, the packaging layer is a thin film packaging layer.

In one embodiment, the bonding terminal is disposed at a target position, and the target position is closer to the at least one connection end of the packaging layer than the at least one connection end of the packaging layer.

In one embodiment, the at least one connection end of the packaging layer is disposed at a border position of the packaging layer corresponding to the at least one connection end of the substrate.

In one embodiment, the surface of the packaging layer further includes a protective layer.

In one embodiment, the protective layer is an inorganic single layer.

In another embodiment, an organic light-emitting diode (OLED) display includes a substrate having at least one connection end, a light-emitting layer formed on the substrate, and a packaging layer covering the light-emitting layer. The packaging layer has at least one connection end formed thereon, and the at least one connection end of the packaging layer is disposed corresponding to the at least one connection end of the substrate. A signal trace and a bonding terminal are disposed on a surface of the packaging layer, a bending extension region is disposed on at least one side of the substrate, the bending extension region is bent to a surface of the packaging layer to electrically connect the at least one connection end of the substrate to the at least one connection end of the packaging layer, and the at least one connection end of the substrate and the least one connection end of the packaging layer are connected to the bonding terminal through the signal trace to transmit a display signal.

In one embodiment, the packaging layer is a packaging cover plate.

In one embodiment, the packaging cover plate and the substrate seal the light-emitting layer by an encapsulant.

In one embodiment, the packaging layer is a thin film packaging layer.

In one embodiment, a thin film packaging single layer or a thin film packaging multilayer is formed on the light-emitting layer, and the bonding terminal is formed on a surface of the thin film packaging layer.

In one embodiment, the bonding terminal is disposed at a target position, and the target position is closer to the at least one connection end of the packaging layer than the at least one connection end of the packaging layer.

In one embodiment, the bonding terminal is disposed at an intermediate position outside the packaging layer.

In one embodiment, the at least one connection end of the packaging layer is disposed at a border position of the packaging layer corresponding to the at least one connection end of the substrate.

In one embodiment, an actual width of the bending extension region is greater than a default width of the bending extension region, and the at least one connection end of the packaging layer is disposed at a position of the surface of the packaging layer for which a projection of the display region to the packaging layer is located

In one embodiment, the bending extension region includes a first bending extension region and a second bending extension region, and the connection end of the packaging layer includes a first connection end of the packaging layer and a second connection end of the packaging layer, and the connection end of the substrate includes a first connection end of the substrate and a second connection end of the substrate, and the first bending extension region is bent to the surface of the packaging layer to electrically connect the first connection end of the packaging layer to the first connection end of the substrate, and the second bending extension region is bent to the surface of the packaging layer to electrically connect the second connection end of the packaging layer to the second connection end of the substrate.

In one embodiment, the surface of the packaging layer further includes a protective layer.

In one embodiment, the protective layer is an inorganic single layer.

The organic light-emitting diode (OLED) display device includes a substrate formed on a light-emitting layer and a light-emitting layer covering the light-emitting layer. A signal trace and a bonding terminal are disposed on a surface of the packaging layer, a bending extension region is disposed on at least one side of the substrate, the bending extension region is bent to a surface of the packaging layer, the at least one connection end of the substrate is electrically connected to the at least one connection end of the packaging layer, and the at least one connection end of the substrate and the at least one connection end of the packaging layer are connected to the bonding terminal through the signal trace to transmit a display signal. The signal trace and a bonding terminal are disposed on an external surface of a packaging layer, so that the OLED display device has an adequate surface space to dispose a low resistance trace. Meanwhile, a bending extension region is disposed on at least one side of the substrate, and display signals can be transmitted nearby so as to reduce attenuation, delay, and nonuniformity. Therefore, the narrow frame of the display device can be advantageously achieved.

### BRIEF DESCRIPTION OF DRAWINGS

In order to more clearly illustrate the technical solutions in the embodiments of the present invention, the drawings of the embodiments will be briefly described below. It is obvious that the drawings in the following description are merely some embodiments of the present invention. Other drawings can also be obtained from those skilled in the art based on these drawings without creative efforts.

FIG. 1 is a schematic view of a back structure of various embodiments of OLED display devices according to one embodiment of the present invention.

FIG. 2 is a schematic view of a back structure of an organic light-emitting diode (OLED) display device according to one embodiment of the present invention.

FIG. 3 is a schematic structural view showing a bending extension region of an OLED display device in an unbent state when a packaging layer is a packaging cover plate according to one embodiment of the present invention.

FIG. 4 is a schematic structural view showing the bending extension region of the OLED display device as shown in FIG. 3 in a bent state according to one embodiment of the present invention.

FIG. 5 is a schematic structural view showing a bending extension region of an OLED display device in an unbent state when a packaging layer is a packaging cover plate according to another embodiment of the present invention.

FIG. 6 is a schematic structural view showing the bending extension region of the OLED display device as shown in FIG. 5 in a bent state according to one embodiment of the present invention.

FIG. 7 is a schematic structural view showing a bending extension region of an OLED display device in an unbent state when a packaging layer is a thin film packaging layer according to one embodiment of the present invention.

FIG. 8 is a schematic structural view showing the bending extension region of the OLED display device as shown in FIG. 7 in a bent state according to one embodiment of the present invention.

### DETAILED DESCRIPTION OF PREFERRED EMBODIMENTS

The technical solutions in the embodiments of the present invention are clearly and completely described in the following with reference to the accompanying drawings in the embodiments of the present invention. It is obvious that the described embodiments are only a part of the embodiments of the present invention, but not all embodiments. All other embodiments obtained by a person skilled in the art based on the present invention without creative efforts are within the claimed scope of the present invention.

In the following description of the present invention, it is to be understood that the terms such as “center,” “longitudinal,” “transversal,” “length,” “width,” “thickness,” “upper,” “lower,” “front,” “back,” “left,” “right,” “vertical,” “horizontal,” “top,” “bottom,” “inside,” “outside,” etc. is based on the orientation shown in the drawings or the positional relationship is merely for the convenience of the description of the present invention and the simplification of the description, and are not intended to indicate or imply that the device or component to have a specific orientation, structures in a specific orientation, and operation, and thus it is not to be construed as limiting the invention. Moreover, the terms “first” and “second” are used for descriptive purposes only and are not to be construed as indicating or implying a relative importance or implicitly indicating the number of technical features indicated. Thus, features defining “first” and “second” may explicitly or implicitly include one or more of the described features. In the description of the present invention, the meaning of “a plurality of” is two or more unless specifically and specifically defined otherwise.

An organic light-emitting diode (OLED) display device is a display made of an organic light-emitting diode. Simultaneously, it has a self-illuminating organic electroluminescent diode and does not require a backlight. Also, the OLED display device has high contrast, a thin thickness, wide viewing angles, fast response times, be capable of being used for flexible panels, wide operating temperature ranges, simple structures, and simple manufacturing processes. It is considered to be the next generation of flat panel display emerging application technology.

As for large-sized OLED display devices, display signals are transmitted from a bonding terminal to each part of the display devices, and display quality is degraded because the large-sized OLED display devices have attenuation, delay, and nonuniformity of transmission of the signals.

In one embodiment, an OLED display device is provided. The OLED display device includes a substrate, a light-emitting layer formed on the substrate, and a packaging layer covering the light-emitting layer. A signal trace and a bonding terminal are disposed on a surface of the packaging layer, a bending extension region is disposed on at least one side of the substrate, the bending extension region is bent to a surface of the packaging layer, and the at least one connection end of the substrate is electrically connected to the at least one connection end of the packaging layer, and the at least one connection end of the substrate and the at least one connection end of the packaging layer are connected to the bonding terminal through the signal trace to transmit a display signal.

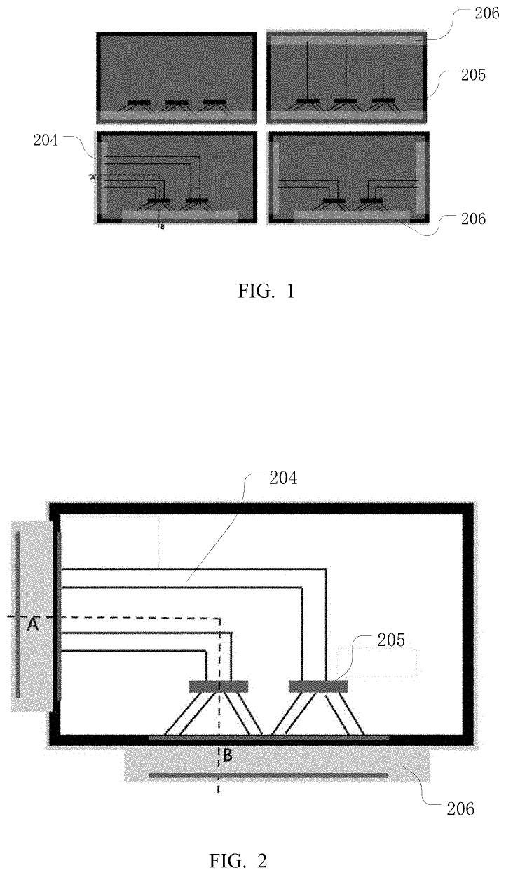

Referring to FIG. 1 to FIG. 8, which are schematic views of an OLED display device according to one embodiment of the present invention. The OLED display device includes:
a substrate 201 having at least one connection end;
a light-emitting layer 202 is formed on the substrate 201; and
a packaging layer 203 covering the light-emitting layer 202. The packaging layer 203 has at least one connection end formed thereon, and the at least one connection end of the packaging layer is disposed corresponding to the at least one connection end of the substrate.

A signal trace 204 and a bonding terminal 205 are disposed on a surface of the packaging layer 203, and a bending extension region 206 is disposed on at least one side of the substrate 201. The bending extension region 206 is bent to a surface of the packaging layer 203 to electrically connected the at least one connection end of the substrate to the at least one connection end of the packaging layer, and the at least one connection end of the substrate and the at least one connection end of the packaging layer are connected to the bonding terminal through the signal trace to transmit a display signal.

A number of the bending extension regions can be the same as the connection end of the packaging layer and the connection end of the substrate. The connection end of the packaging layer and the connection end of the substrate correspondingly disposed means that each connection end of the substrate is disposed and corresponded to the connection end of the packaging layer, and the connection end of the substrate is disposed at a corresponding position of the bending extension region, so that the connection end of the packaging layer is electrically connected to the connection end of the substrate when the bending extension region is bent to the surface of the packaging layer.

In one embodiment, an OLED display device is provided. The OLED display device includes a substrate, a light-emitting layer formed on the substrate, and a packaging layer covering the light-emitting layer. A signal trace and a bonding terminal are disposed on a surface of the packaging layer, a bending extension region is disposed on at least one side of the substrate, the bending extension region is bent to a surface of the packaging layer, and the at least one connection end of the substrate is electrically connected to the at least one connection end of the packaging layer, and the at least one connection end of the substrate and the at least one connection end of the packaging layer are connected to the bonding terminal through the signal trace to transmit a display signal. In the embodiment, the signal trace and the bonding terminal are disposed on an external surface of the packaging layer, so that the OLED display device has an adequate surface space to dispose a low resistance trace. Meanwhile, the bending extension region is disposed on at least one side of the substrate, and the display signals can be transmitted nearby, so that attenuation, delay, and nonuniformity can be reduced. Therefore, a narrow frame of the display device can be advantageously achieved.

Referring to FIG. 1, which is a schematic view of a back structure of various embodiments of OLED display devices according to one embodiment of the present invention. In the embodiment, a bending extension region 206 is disposed on at least one side of the substrate 201, and a first side of the substrate (the upper left corner of FIG. 1), a second side (the upper right corner and the lower left corner of FIG. 1), and a third side (the lower right corner of FIG. 1) are provided with the bending extension region 206. Specifically, the bending extension region 206 disposed on at least one side of the substrate 201 can be that, for example, an upper side and a lower side of the substrate 201 is provided with the bending extension region 206, and a left and a right side are provided with the bending extension region 206, or the upper side and the left side are provided with the bending extension region 206, and the upper side, lower side, and left side are provided with the bending extension region 206, and so on. Also, all sides of substrate are provided with the bending extension region 206, and it is not specifically illustrated herein.

When two or more sides of the substrate 201 are provided with the bending extension region 206, the bonding terminal may be one, two, or even more. As shown in FIG. 2, the left and lower sides of the substrate 201 are provide with the bending extension region 206 and two bonding terminals 205. When two adjacent sides are provided with the bending extension region 206, at least one side of the substrate 201 is cutting or edging.

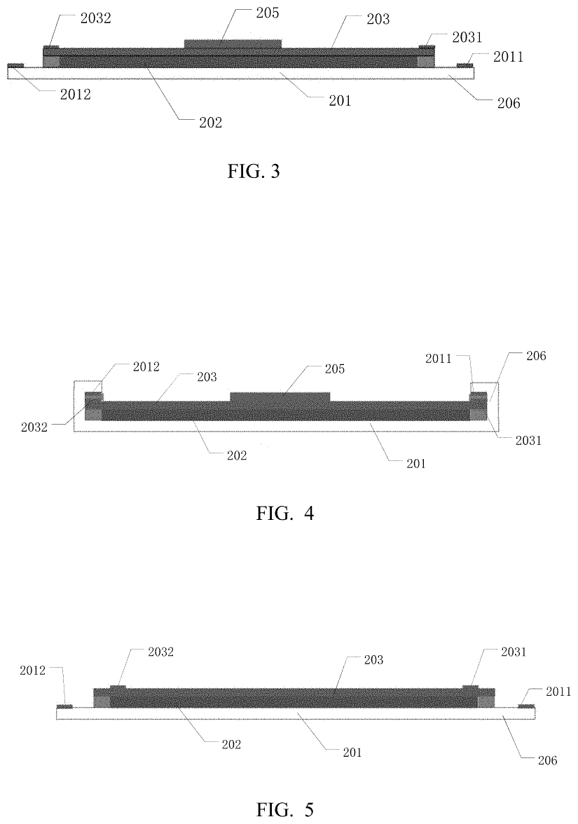

Referring to FIG. 3 to FIG. 8, in one embodiment, the bending extension region includes a first bending extension region and a second bending extension region, and the connection end of the packaging layer includes a first connection end of a packaging layer 2031 and a second connection end of a packaging layer 2032, and the connection end of the substrate includes a first connection end of a substrate 2011 and a second connection end of a substrate 2012, and the first bending extension region is bent to the surface of the packaging layer to electrically connect the first connection end of the packaging layer 2031 connected to the first connection end of the substrate 2011, and the second bending extension region is bent to the surface of the packaging layer to electrically connect the second connection end of the packaging layer 2032 to the second connection end of the substrate 2012.

In one embodiment, there are various package modes for the packaging layer 203, for example, the packaging layer 203 can be a packaging cover plate or a thin film packaging layer. When the packaging layer 203 is a packaging cover plate, the packaging cover plate and the substrate 201 seal the light-emitting layer by an encapsulant. FIG. 3 and FIG. 4 are schematic structural views showing a bending extension region 206 of an OLED display device is respectively unbent and bent when a packaging layer 203 is a packaging cover plate. The bonding terminal 205 and the signal trace 204 disposed on the external surface of the packaging layer 203 is illustrated in FIG. 1. The packaging cover plate of the packaging layer 203 and the substrate 201 seal the light-emitting layer by an encapsulant. The signal trace 204 and the bonding terminal 205 are disposed on the external surface of the packaging layer 203, and the bending extension region 206 is reserved when the substrate 201 is cutting. At least one connection end of the substrate is disposed in the bending extension region 206, and at least one connection end of the packaging layer is disposed at a corresponding frame portion of the packaging layer. After the packaging process is completed, the bending extension region 206 of the substrate 201 is bent, and the at least one connection end of the substrate is electrically connected to the at least one connection end of the packaging layer. Specifically, when the packaging cover plate and the substrate 201 are sealed by the encapsulant, an anisotropic conductive film (ACF), a nonconductive film (NCF) adhesive, or the like can be adopted. The connection end of the surface of the packaging layer 203 is electrically connected to the bonding terminal 205. At this time, since the signal trace 204 and the bonding terminal 205 are disposed on the external surface of the packaging layer, the display device has an adequate surface space to dispose a low resistance trace, thereby reducing attenuation, delay, and nonuniformity of transmission of signals. Accordingly, quality of a screen of the OLED display device is improved.

In addition, in the embodiment, the connection end of the packaging layer 203, the signal trace 204, and the bonding terminal 205 disposed on the packaging layer 203 can be formed on the surface of the packaging layer of the display device after the packaging process is completed. Also, it may also be formed on a surface of the packaging cover plate of the packaging layer 203 before the packaging process, which is not limited herein.

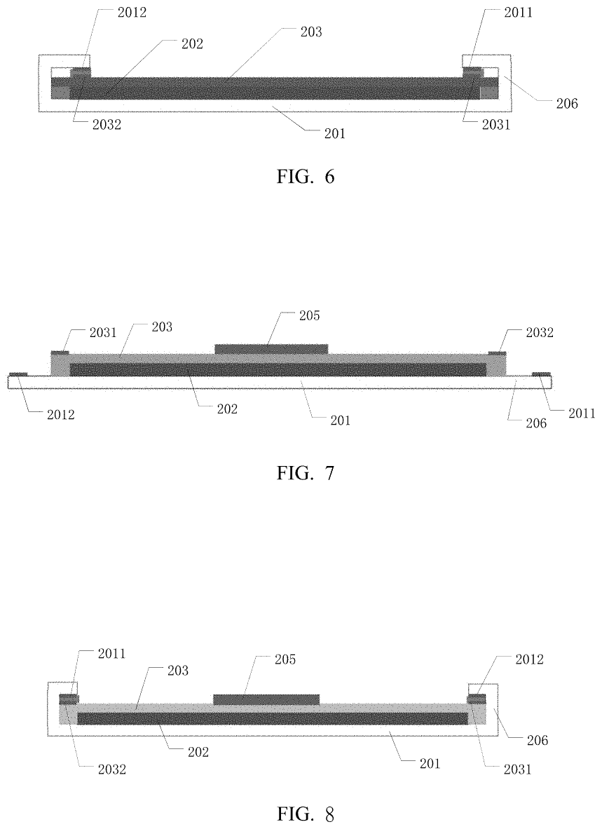

FIG. 5 and FIG. 6 are schematic structural views showing a bending extension region of another OLED display device which is respectively unbent and bent when a packaging layer 203 is a packaging cover plate. Some of structures, such as bonding terminals, are not shown in the drawings. The bending extension region 206 of the substrate 201 is provided with an adequate width, that is the bending extension region 206 has a larger preset than the above embodiment. In other words, the at least one connection end of the packaging layer is disposed at a position of the surface of the packaging layer 203 for which a projection of the display region to the packaging layer 203 is located, an actual width of the bending extension region 206 is greater than a default width of the bending extension region. There is a larger space to bend the substrate, which is advantageous for electrically connecting the substrate connection end and the connection end of the packaging layer.

FIG. 8 and FIG. 9 are schematic structural views showing a bending extension region 206 of another OLED display device is respectively unbent and bent when a packaging layer 203 is a thin film packaging layer. A thin film packaging single layer or a thin film packaging multilayer is formed on the light-emitting layer, and the bonding terminal 205 is formed on a surface of the thin film packaging layer.

In some embodiments, the bonding terminal 205 is disposed at a target position, and the target position is closer to the at least one connection end of the packaging layer than the at least one connection end of the packaging layer. It can be understood that there are other arrangements, such as the bonding terminal 205 being disposed at an intermediate position outside the packaging layer 203. Moreover, the at least one connection end of the packaging layer is disposed at a border position of the packaging layer 203 corresponding to the at least one connection end of the substrate.

Preferably, the bending extension region 206 of the substrate 201 can further includes driving circuits, for example, an electrostatic discharge (ESD) circuit and/or a gate driving circuit. Each driving circuit may also be partially or entirely disposed on the surface of the packaging layer, which is advantageous for reducing a width of the frame of the display device, for example, each driving circuit is disposed between the connection end of the packaging layer and the bonding terminal.

Compared with the above embodiments, in some embodiments of the present invention, the connection end of the packaging layer 203, the signal trace, and the bonding terminal disposed of the surface of the packaging layer 203 may further include a protective layer. The protective layer may be an inorganic single layer, for example, SiNx, SiOx, and so on. The protective layer may also be an organic single layer, such as polyimide (PI), polycarbonate (PC), polyethersulfone (PES), polyethylene terephthalate (PET), and so on. The protective layer may also be a multilayered stack structure made of inorganic layers or organic layer. Further, the protective layer can cover a signal trace or the like to expose the connection end and the bonding terminal 205 of the packaging layer.

It should be noted that, in order to facilitate to bend the bending extension region 206 disposed on the substrate 201, material of the substrate is preferably a flexible polymer material, such as polyimide (PI), polycarbonate (PC), polyethersulfone (PES), polyethylene terephthalate (PET), polyethylene naphthalate (PEN), polyarylate (PAR), or glass fiber reinforced plastic (FRP). In some embodiments, the substrate may be a two-layered structure including a first substrate and a second substrate. The first substrate may be a material such as glass or transparent metal. The second substrate may be a flexible material. The second substrate is disposed on the first substrate, and the light-emitting layer is formed on the second substrate, and a bending extension region is disposed on the second substrate, such as the first bending extension region and the second bending extension region as described above.

In the above-mentioned embodiments, the descriptions of the various embodiments are described. If a part of the descriptions is not detailed in one embodiment, it can be found in the above detailed description of the OLED display and will not be described herein. The specific implementation can be referred to the embodiments, and details are not described herein

An OLED display provided by one embodiment of the present invention is described in detail.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. An organic light-emitting diode (OLED) display device, comprising:
a substrate, wherein the substrate comprises at least one connection end;
a light-emitting layer, wherein the light-emitting layer is formed on the substrate; and
a packaging layer, wherein the packaging layer covers the light-emitting layer, the packaging layer has at least one connection end formed thereon, and the at least one connection end of the packaging layer is disposed corresponding to the at least one connection end of the substrate;
wherein a signal trace and a bonding terminal are disposed on a surface of the packaging layer, a bending extension region is disposed on at least one side of the substrate, the bending extension region is bent to a surface of the packaging layer to electrically connect the at least one connection end of the substrate to the at least one connection end of the packaging layer, and the at least one connection end of the substrate and the at least one connection end of the packaging layer are connected to the bonding terminal through the signal trace to transmit a display signal;
wherein an actual width of the bending extension region is greater than a default width of the bending extension region, and the at least one connection end of the packaging layer is disposed at a position of the surface of the packaging layer for which a projection of the display region to the packaging layer is located; and
wherein the bonding terminal is disposed at an intermediate position of an outside the packaging layer.

2. The OLED display device according to claim 1, wherein the packaging layer is a packaging cover plate.

3. The OLED display device according to claim 2, wherein the packaging cover plate and the substrate seal the light-emitting layer by an encapsulant.

4. The OLED display device according to claim 3, wherein the packaging layer is a thin film packaging layer.

5. The OLED display device according to claim 1, wherein the bonding terminal is disposed at a target position, and the target position is closer to the at least one connection end of the packaging layer than the at least one connection end of the packaging layer.

6. The OLED display device according to claim 1, wherein the at least one connection end of the packaging layer is disposed at a border position of the packaging layer corresponding to the at least one connection end of the substrate.

7. The OLED display device according to claim 1, wherein the surface of the packaging layer further comprises a protective layer.

8. The OLED display device according to claim 6, wherein the protective layer is an inorganic single layer.

9. An organic light-emitting diode (OLED) display device, comprising:
a substrate, wherein the substrate comprises at least one connection end;
a light-emitting layer, wherein the light-emitting layer is formed on the substrate; and
a packaging layer, wherein the packaging layer covers the light-emitting layer, the packaging layer has at least one connection end formed thereon, and the at least one connection end of the packaging layer is disposed corresponding to the at least one connection end of the substrate;
wherein a signal trace and a bonding terminal are disposed on a surface of the packaging layer, a bending extension region is disposed on at least one side of the substrate, the bending extension region is bent to a surface of the packaging layer to electrically connect the at least one connection end of the substrate to the at least one connection end of the packaging layer, and the at least one connection end of the substrate and the least one connection end of the packaging layer are connected to the bonding terminal through the signal trace to transmit a display signal.

10. The OLED display device according to claim 9, wherein the packaging layer is a packaging cover plate.

11. The OLED display device according to claim 10, wherein the packaging cover plate and the substrate seal the light-emitting layer by an encapsulant.

12. The OLED display device according to claim 11, wherein the packaging layer is a thin film packaging layer.

13. The OLED display device according to claim 12, wherein a thin film packaging single layer or a thin film packaging multilayer is formed on the light-emitting layer, and the bonding terminal is formed on a surface of the thin film packaging layer.

14. The OLED display device according to claim 9, wherein the bonding terminal is disposed at a target position, and the target position is closer to the at least one connection end of the packaging layer than the at least one connection end of the packaging layer.

15. The OLED display device according to claim 9, wherein the bonding terminal is disposed at an intermediate position outside the packaging layer.

16. The OLED display device according to claim 9, wherein the at least one connection end of the packaging layer is disposed at a border position of the packaging layer corresponding to the at least one connection end of the substrate.

17. The OLED display device according to claim 9, wherein an actual width of the bending extension region is greater than a default width of the bending extension region, and the at least one connection end of the packaging layer is disposed at a position of the surface of the packaging layer for which a projection of the display region to the packaging layer is located

18. The OLED display device according to claim 9, wherein the bending extension region comprises a first bending extension region and a second bending extension region, and the connection end of the packaging layer comprises a first connection end of the packaging layer and a second connection end of the packaging layer, and the connection end of the substrate comprises a first connection end of the substrate and a second connection end of the substrate, and the first bending extension region is bent to the surface of the packaging layer to electrically connected the first connection end of the packaging layer to the first connection end of the substrate, and the second bending extension region is bent to the surface of the packaging layer to electrically connect the second connection end of the packaging layer to the second connection end of the substrate.

19. The OLED display device according to claim 9, wherein the surface of the packaging layer further comprises a protective layer.

20. The OLED display device according to claim 19, wherein the protective layer is an inorganic single layer.
